(19) United States
(12) Patent Application Publication
(10) Pub. No.: US 2021/0384879 A1
(43) Pub. Date: Dec. 9, 2021

(54) ACOUSTIC SIGNAL PROCESSING DEVICE, ACOUSTIC SIGNAL PROCESSING METHOD, AND NON-TRANSITORY COMPUTER-READABLE RECORDING MEDIUM THEREFOR

(71) Applicant: Faurecia Clarion Electronics Co., Ltd., Saitama-shi (JP)

(72) Inventor: Toshihiro FUEKI, Saitama-shi (JP)

(73) Assignee: Faurecia Clarion Electronics Co., Ltd., Saitama-shi (JP)

(21) Appl. No.: 17/337,642

(22) Filed: Jun. 3, 2021

(30) Foreign Application Priority Data
Jun. 4, 2020 (JP) 2020-097847

(51) Int. Cl. H03G 3/00; H03G 3/18; H04R 3/04

(52) U.S. Cl. CPC H03G 3/005; H04R 2430/01; H04R 3/04; H03G 3/18

(57) ABSTRACT

According to aspects of the present disclosures, an acoustic signal processing device includes a sound pressure measurement section configured to measure a sound pressure of a sound output from a speaker, a recording level obtaining section configured to obtain a recording level of an audio signal which is a signal representing the sound, and a gain increasing section configured to increase a gain to the audio signal when the sound pressure measured by the sound pressure measurement section is equal to or larger than a first threshold and the recording level obtained by the recording level obtaining section is less than a second threshold.

### CROSS-REFERENCE TO RELATED APPLICATIONS

This application claims priority under 35 § 119 from Japanese Patent Application No. 2020-097847 filed on Jun. 4, 2020. The entire subject matter of the application is incorporated herein by reference.

### BACKGROUND

### Technical Field

The present disclosures relate to an acoustic signal processing device, an acoustic signal processing method, and a non-transitory computer-readable recording medium storing computer-executable instructions realizing an acoustic signal processing program.

### Related Art

Conventionally, there has been known an acoustic signal processing device configured to perform a loudness control. The human ear has a characteristic of having more difficulty hearing bass and treble sounds when a volume is lower. In order to compensate for the above characteristic, the loudness control is linked to a volume control (e.g., a volume knob) such that the lower the volume is, the more the bass and treble sounds are enhanced.

Such a conventional acoustic signal processing device is typically configured to calculate a final perceived volume level of the user and adjust the loudness based on the calculated perceived volume level, thereby making it possible to make a speaker output a sound such as a piece of music at an appropriate volume for the user while maintaining a dynamic range of the original sound.

### SUMMARY

There is a demand to reduce the size and weight of speakers, and to reduce manufacturing costs thereof. As a way to meet this demand, a possible solution is to reduce the size of the magnet mounted on the speaker. However, when the magnet is made smaller, the sound pressure of the sound output from the speaker is reduced.

Therefore, it is possible to compensate for deterioration of speaker characteristics (i.e., decrease in the sound pressure of the sound output from the speaker) due to downsizing of the magnet by applying the above-mentioned conventional acoustic signal processing method (hereinafter, referred to as the conventional method). However, for music with a small recording level, such as classical music, even if the conventional method is applied to enhance the low and high frequencies, the sound pressure may not increase sufficiently to compensate for the deterioration in the speaker characteristics. In other words, depending on the content of the sound (for example, for music with a small recording level such as classical music), it is difficult to satisfy the user's demand to listen to the sound with a high sound pressure with the use of the conventional method.

According to aspects of the present disclosures, there is provided an acoustic signal processing device, including a sound pressure measurement section configured to measure a sound pressure of a sound output from a speaker, a recording level obtaining section configured to obtain a recording level of an audio signal which is a signal representing the sound, and a gain increasing section configured to increase a gain to the audio signal when the sound pressure measured by the sound pressure measurement section is equal to or larger than a first threshold and the recording level obtained by the recording level obtaining section is less than a second threshold.

According to aspects of the present disclosures, the acoustic signal processing device includes a volume controller configured to receive a user operation to adjust a volume of the sound. When the volume controller is operated to adjust the volume, the gain increasing section increases the gain to the audio signal on condition that the sound pressure measured by the sound pressure measurement section is equal to or larger than the first threshold and the recording level obtained by the recording level obtaining section is less than the second threshold.

According to aspects of the present disclosures, the acoustic signal processing device includes a band divider dividing the audio signal to a plurality of frequency bands, and a compensation section configured to compensate the audio signal of each of the frequency bands divided by the band divider using a different filtering coefficient.

According to aspects of the present disclosures, the acoustic signal processing device includes a filter coefficient storage configured to store default filtering coefficient. When the sound pressure measured by the sound pressure measurement section is less than the first threshold, the compensation section is configured to compensate for the audio signal using the default filtering coefficient.

According to aspects of the present disclosures, the gain increasing section is configured to increase the gain to the audio signal so that a peak sound pressure level of the audio signal becomes a full scale.

According to aspects of the present disclosures, there is provided a non-transitory computer-readable recording medium for an acoustic signal processing device having a controller, the recording medium storing instructions which cause, when executed by the controller, the acoustic signal processing device to perform measuring a sound pressure of a sound output from a speaker, obtaining a recording level of an audio signal which is a signal representing the sound, and increasing a gain to the audio signal when the sound pressure is equal to or larger than a first threshold and the recording level is less than a second threshold.

### BRIEF DESCRIPTION OF THE DRAWINGS

FIG. 1 is a block diagram of an acoustic signal processing device according to an embodiment of the present disclosures.

FIG. 2 is a flowchart illustrating an acoustic signal processing process executed by a DSP of the acoustic signal processing device according to the embodiment of the present disclosures.

FIG. 3 is a graph showing an example of filter coefficients according to the embodiment of the present disclosures.

### DETAILED DESCRIPTION OF THE EMBODIMENT

An embodiment of the present disclosures will be described with reference to the drawings. As the embodiment of the present disclosures, an acoustic signal processing device capable of satisfying requirements of both users who place importance on sound pressure and users who place importance on sound quality will be described.

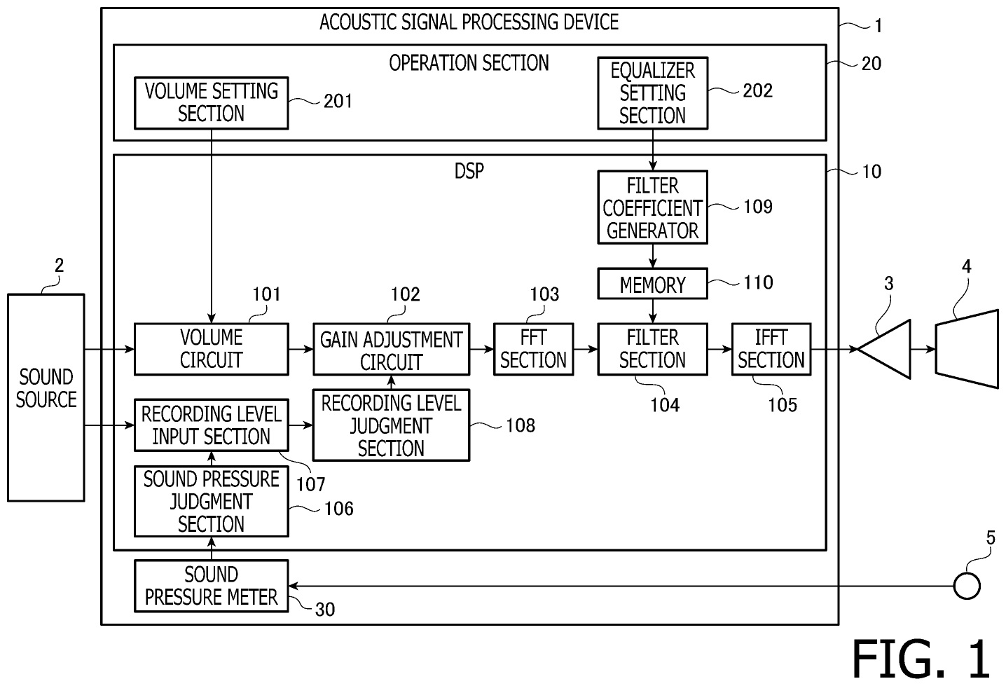

FIG. 1 shows a block diagram of an acoustic signal processing device 1. The acoustic signal processing device 1 is an audio device that constitutes an audio system installed, for example, in a vehicle.

The acoustic signal processing device 1 is not necessarily be limited to a device installed in a vehicle, but may also be a device installed indoors. Further, the acoustic signal processing device 1 may be built into portable devices such as smartphones, feature phones, PHS's (Personal Handy phone System), tablet terminals, notebook PCs, PDA's (Personal Digital Assistant), PND's (Portable Navigation Device), portable game machines, etc.

The acoustic signal processing device 1 performs particular acoustic signal processing on the audio signal input from a sound source 2, and outputs the processed audio signal to a speaker 4 via an amplifier 3. Accordingly, a user can listen to the music output by the sound source. The sound source 2 is, for example, a disc media such as a CD (Compact Disc), an SACD (Super Audio CD), etc., or a storage media such as an HDD (Hard Disk Drive), a USB (Universal Serial Bus) memory, etc.

As shown in FIG. 1, the acoustic signal processing device 1 is equipped with a DSP (Digital Signal Processor) 10, an operation unit 20 and a sound pressure meter 30. It is noted that, In FIG. 1, main components necessary for the description of this embodiment are illustrated, and some components, for example, a housing, which is normally provided to the acoustic signal processing device 1, are omitted as appropriate.

The DSP 10 has a volume circuit 101, a gain adjustment circuit 102, an FFT (Fast Fourier Transform) section 103, a filter section 104, an IFFT (Inverse Fast Fourier Transform) section 105, a sound pressure judgment section 106, a recording level input section 107, a recording level judgment section 108, a filter coefficient generator 109, and a memory 110.

The operation unit 20 has a volume setting section 201 and an equalizer setting section 202.

The volume setting section 201 is an operation section that is operated by the user for adjusting the volume. When the volume setting section 201 is operated by the user, volume change information corresponding to the operation is input to the volume circuit 101. In addition, an audio signal is input to the volume circuit 101 from the sound source 2.

The volume circuit 101 attenuates a signal level (unit: dB) of the audio signal input from the sound source 2 based on the volume change information. For example, when the volume change information is −6 dB, the signal level of the audio signal is adjusted to about 0.5 times (−6 dB≈0.5 times).

As above, the volume circuit 101 operates as a volume controller that receives the user's operation of the volume setting section 201 and adjusts a signal level of the audio signal input from the sound source 2. It is noted that the signal level of the audio signal here is equivalent to the volume of the sound output based on the audio signal.

The equalizer setting section 202 is configured to be operated by the user to adjust the gain for each frequency band. When the equalizer setting section 202 is operated by the user, a filter coefficient corresponding to the operation is generated by the filter coefficient generator 109, and the generated filter coefficient is stored in the memory 110. The default filter coefficient is stored in the memory 110 in advance. In other words, the memory 110 operates as a filter coefficient storage unit that stores the default filter coefficient.

The audio signal input from the sound source 2 to the DSP 10 is input to the FFT section 103 through the volume circuit 101 and the gain adjustment circuit 102. The FFT section 103 converts the audio signal input from the gain adjustment circuit 102 from a time-domain signal to a frequency domain signal. Specifically, the FFT section 103 converts the time domain signal to the frequency domain signal by applying an overlap process and weighting with use of a window function to the audio signal input from the gain adjustment circuit 102, and then performing a short-time Fourier transform process. As a result, a frequency spectrum signal including a real part and an imaginary part is obtained.

The filter section 104 applies a filter process to the audio signal having been converted into the frequency domain signal by the FFT section 103 using the filter coefficient stored in the memory 110. It is noted that the filter coefficient for each frequency band is stored in the memory 110. The filter section 104 multiplies the audio signal of each frequency band divided by the FFT section 103 by the filter coefficient of the corresponding frequency band. Then, the filter section 104 outputs the frequency domain audio signals weighted by this multiplication process to the IFFT section 105.

The IFFT section 105 converts the audio signals multiplied by the filter section 104 from the frequency domain signal to the time domain signal. Specifically, the IFFT section 105 transforms the audio signal from the frequency domain signal to the time domain signal by applying a short-time inverse Fourier transform to the audio signal. The IFFT section 105 further performs the weighting process with use of a window function and an overlap addition. With the above processes, the IFFT section 105 obtains an audio signal in the time domain that has been compensated, for each frequency band, by a filter process using the filter coefficients. As the thus processed audio signal is output to the speaker 4 via the amplifier 3, the user can listen to music or the like in an equalized manner. In other words, by operating the equalizer setting section 202, the user can listen to the music or the like equalized to the desired sound quality.

As described above, the FFT section 103 operates as a band divider that divides the audio signal into multiple frequency bands. Further, the filter section 104 operates as a compensation section that compensates the audio signal in each frequency band divided by the band division section with different filter coefficients.

The sound pressure meter 30 is a sensor configured to measure sound pressure (unit: dB). According to the present embodiment, the microphone 5 is connected to the sound pressure meter 30, and the sound pressure meter 30 measures the sound pressure of the sound collected by the microphone 5.

The microphone 5 is arranged near a user's head, for example. Therefore, when a sound such as a sound of a piece of music is being output from the speaker 4, the sound pressure meter 30 measures the sound pressure of the sound output from the speaker 4, which is in effect the sound that the user hears.

Thus, the sound pressure meter 30 operates as a sound pressure measurement section configured to measure the sound pressure of the sound output from the speaker 4.

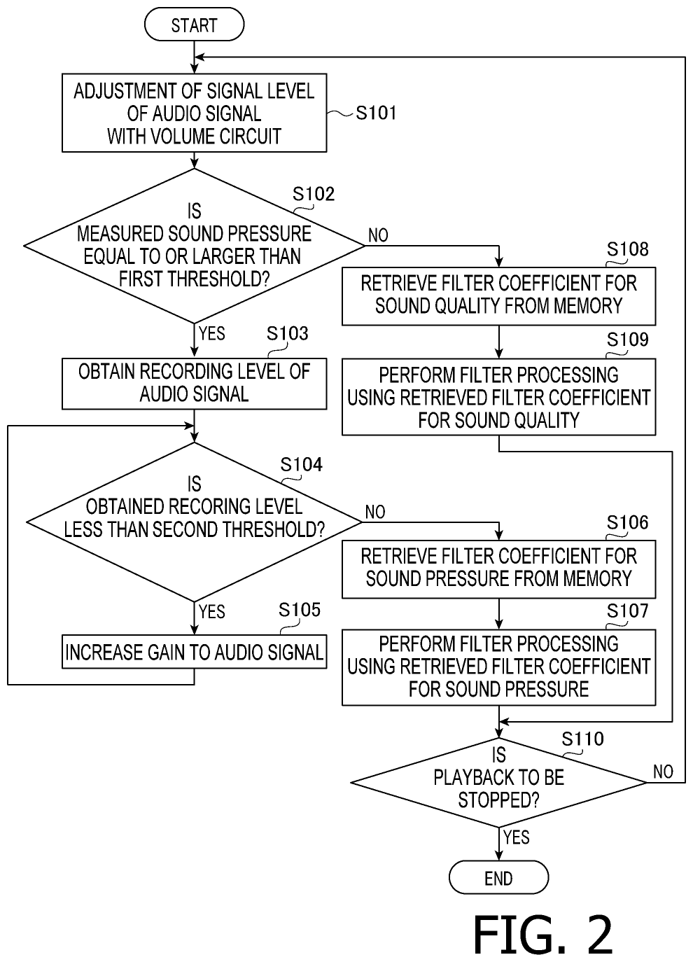

FIG. 2 shows a flowchart illustrating the acoustic signal processing process executed by the DSP 10. The DSP 10 starts executing the acoustic signal processing process shown in FIG. 2 in response to input of an audio signal from the sound source 2. The DSP 10 may include a memory storing a program for executing the acoustic signal processing process, or the DSP 10 may connected to a memory (not shown) storing the program and read the program from the memory.

As shown in FIG. 2, when the signal level of the audio signal is adjusted by the volume circuit 101 (step S101), the sound pressure judgment section 106 judges whether or not the sound pressure measured by the sound pressure meter 30 (as described above, the sound pressure of the sound which is output from the speaker 4 and heard by the user) is equal to or larger than a first threshold (step S102).

It is noted that the sound pressure measured by the sound pressure meter 30 includes error components such as dark noise in the vehicle interior and road noise during driving. Therefore, the sound pressure judging unit 106 performs the threshold judgment in step S102 after applying a filter processing to the sound pressure measured by the sound pressure meter 30 in order to reduce such error components. The filter processing includes, for example, a characteristic filter.

In this embodiment, the first threshold is 88 dB. Although this threshold is an exemplary value, it is determined in consideration of general music listening.

The basic idea of equalization is to improve the sound quality by cutting the frequency components that are excessive or of which peaks are noticeable and annoying, taking into consideration the distortion of the sound signal by the amplifier and the load and performance limit of the speaker. However, when the frequency components are cut as described above, the sound pressure is reduced. Therefore, it is difficult to meet the demands of users who want to listen to music at high volume.

Therefore, in this embodiment, when the sound pressure measured by the sound pressure meter 30 (more specifically, the sound pressure after the above-mentioned filter processing) is equal to or larger than the first threshold, signal processing is performed with emphasis on the sound pressure, assuming that the user desires to listen to the music or other sounds at a high volume. On the other hand, when the measured sound pressure is less than the first threshold, signal processing is performed with emphasis on the sound quality, assuming that the user desires to listen to the music or other sounds with emphasis on the sound quality.

When the measured sound pressure measured by the sound pressure meter 30 is less than 75 dB, it is considered that the user may be listening to the music as background music. Further, when the measured sound pressure is between 75 dB and 83 dB, it is assumed that the user may be listening to the music with an emphasis on the sound quality. When the measured sound pressure is between 83 dB and 88 dB, it is assumed that the user may be listening to the music at a certain level of loudness while placing importance on the sound quality. According to the present embodiment, in the above cases, signal processing that emphasizes sound quality is performed assuming that the user wants to listen to the music and other sounds with an emphasis on sound quality.

When the measured sound pressure is 88 dB or higher, it is assumed that the user may be listening to the music at a high volume without regard to the sound quality, and the signal processing with emphasis on sound pressure is performed.

As above, by switching the content of signal processing according to the sound pressure of the sound that the user is actually listening to, it becomes possible to satisfy the requirements of both users who place importance on sound pressure and users who place importance on sound quality.

It is noted that the audio signal is not the only signal that is input from sound source 2 to DSP 10. For example, the recording level (unit: dB) of the audio signal obtained as a result of the seek process performed before playback of the audio signal is also input from the sound source 2 to the DSP 10 (more specifically, the recording level input section 107). According to the present embodiment, the recording level for each music piece is input to the recording level. input section 107. The DSP 10 is an example of a controller storing instructions.

When the sound pressure measured by the sound pressure meter 30 is 88 dB or higher (S102: YES), the recording level judgment section 108 obtains the recording level of the audio signal (i.e., the audio signal of the currently playing music) from the recording level input section 107 (step S103). Thus, the recording level judgment section 108 operates as a recording level obtaining section to obtain the recording level of the audio signal.

The recording level judgment section 108 determines whether the recording level obtained from the recording level input section 107 is less than a second threshold (step S104). That is, the recording level judgment section 108 determines whether the sound pressure level of the peak of the recording level of the music currently being played is less than the second threshold. In this embodiment, a full scale (unit: dB), which is the maximum value that can be represented by a digital signal, is used as the second threshold.

When the peak sound pressure level of the recording level of the music currently being played is less than the second threshold (S104: YES), the gain adjustment circuit 102 increases the gain to the audio signal input from the volume circuit 101 so that the sound pressure level of this peak becomes the full scale (S105). In other words, the gain adjustment circuit 102 operates as a gain increasing section that increases the gain to the audio signal when the sound pressure measured by the sound pressure measurement section is higher than the first threshold level and the recording level obtained by the recording level obtaining section is lower than the second threshold level.

When the sound pressure level exceeds the full scale, the sound is distorted in an area that exceeds the full scale. Therefore, according to the present embodiment, the gain is increased, in such a case, so that the peak sound pressure level does not exceed the full scale.

In the memory 110, filter coefficients with emphasis on sound pressure (hereinafter, referred to as “filter coefficients for sound pressure”) and filter coefficients with emphasis on sound quality (hereinafter, referred to as “filter coefficients for sound quality”) are stored in advance.

When the peak sound pressure level of the recording level of the music currently being played (or the peak sound pressure level after the gain increase by the gain adjustment circuit 102) is equal to the second threshold (i.e., the full scale) (S104: NO), the filter section 104 retrieves the filter coefficients for sound pressure from the memory 110 (S106) and performs the filter processing using the retrieved filter coefficients for sound pressure (S107). As the audio signal is output to the speaker 4 via the amplifier 3, the user (specifically, a user who is assumed to desire to listen to a piece of music or the like at a high volume) can hear the sound of a piece of music or the like of which volume has been increased by raising the peak sound pressure level to the full scale by the gain adjustment circuit 102. Therefore, the user can listen to the music, etc. with equalization focused on the sound pressure.

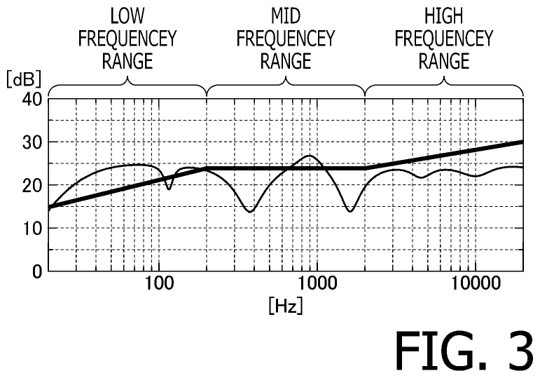

FIG. 3 shows an example of the filter coefficients. In FIG. 3, the vertical axis indicates the sound pressure level (unit: dB), and the horizontal axis indicates the frequency (unit: Hz). In FIG. 3, the thick line shows an example of the filter coefficient for sound pressure. The thin line in FIG. 3 shows an example of a filter coefficient for sound quality. In the example in FIG. 3, the audio signal is divided into three frequency bands (low, mid, and high) by the FFT section 103, and the filter section 104 performs the filter processing for each frequency band using the corresponding filter coefficients.

Next, the filter processing using the filter coefficients for sound pressure will be described. Concretely, for a low frequency range (in this case, less than 200 Hz), where distortion is likely to occur when the volume is increased, the filter processing is performed using the filter coefficient for the low frequency range so that the sound pressure decreases as the frequency decreases. For a mid-range (in this case, between 200 Hz and 2000 Hz), which includes the main sound such as vocals, the filter processing with flat characteristics is performed using the filter coefficient for the mid-range. For the high frequency range (in this case, above 2000 Hz). where distortion is less noticeable even when the volume is increased, the sound pressure increases as the frequency increases, using the filter coefficient for the high frequency range to compensate for the decrease in sound pressure caused by attenuating the low frequency range.

The filter coefficient for sound pressure shown in FIG. 3 is a coefficient designed for a speaker of which low frequency range is easily distorted (for example, a speaker with a small diameter). When the speaker 4 connected to the acoustic signal processing device 1 does not distort easily even in the low frequency range (e.g., a speaker with a large diameter), the filter processing using filter coefficients for sound pressure different from those shown in FIG. 3 (e.g., the filter processing with flat characteristics in the low frequency range or the filter processing that increases the sound pressure in the low frequency range) may be performed.

In the example shown in FIG. 3, the audio signal is divided into three frequency bands (low, mid, and high), and the multiplication process using filter coefficients is performed for each of these frequency bands. However, the present disclosures should not be limited to such a configuration. In another embodiment, the audio signal may he divided into two, four or more frequency bands (as an example, low, mid-low, mid-high, and high), and the multiplication process using filter coefficients is performed for each of these frequency bands.

When the measured sound pressure measured by the sound pressure meter 30 is less than 88 dB (S102: NO), the gain adjustment by the gain adjustment circuit 102 is not performed. In other words, the gain adjustment circuit 102 through-outputs the audio signal input from the volume circuit 101 to the FFT section 103. The filter section 104 retrieves the filter coefficients for sound quality from the memory 110 (step S108) and performs the filter processing using the retrieved filter coefficients for sound quality (step S109). That is, the filter section 104, which operates as a compensation section, compensates the audio signal with the default filter coefficients stored in the filter coefficient storage section when the sound pressure below the first threshold is measured by the sound pressure measurement section.

As the audio signal after the filter processing in step S109 is output to the speaker 4 through the amplifier 3, the user (specifically, the user who is supposed to want to listen to a music, etc. with an emphasis on sound quality) can listen to the music piece, etc. with an emphasis on sound quality equalization. The filter coefficients for sound quality shown in FIG. 3 are designed to improve sound quality by cutting frequency components that are excessive or of which peaks are noticeable and annoying, taking into consideration the distortion of the amplifier and the load and performance limits of the speaker.

Until there is no more input of audio signals from the sound source 2 (i.e., until the playback of the music, etc. is stopped) (S110: YES), the acoustic signal processing process shown in FIG. 2 is continuously performed.

It is assumed that a user who wants to listen to a sound with a large sound pressure will perform an operation to the volume setting section 201 and increase the volume even if the recording level of the music is small, for example, classical music. In this embodiment, when the sound pressure measured by the sound pressure meter 30 becomes 88 dB or higher due to the increase in volume, the gain adjustment circuit 102 raises the peak sound pressure level to the full scale, so that the volume of the music, etc. increases, and the music, etc. with equalization focusing on the sound pressure is output from the speaker 4. In other words, according to the present embodiment, the user's demand to listen to sound with high sound pressure regardless of the content of the sound is satisfied (even if the recording level of the music is small, such as classical music).

It is assumed that users who place importance on sound quality will not raise the volume excessively (up to 88 dB). In the present embodiment, when the sound pressure measured by the sound pressure meter 30 is less than 88 dB, music with equalization that emphasizes the sound quality is output from the speaker 4. In other words, according to the present embodiment, the user's demand to listen to sound with high sound quality regardless of the sound content is satisfied (even if the music has a high recording level, such as rock music, for example).

In the present embodiment, when the signal level of the audio signal is adjusted by the volume circuit 101, the first threshold is used to determine whether the user places emphasis on the sound pressure or sound quality. It is because the user operation of increasing the volume by the volume setting unit 201 may indicate the user's intention to listen to music at a high volume. It is noted, however, that the timing to determine whether the user is focusing on sound pressure or sound quality is not limited to the timing when the signal level of the audio signal is adjusted by the volume circuit 101. Instead of or in addition to the above timing, whether the user is focusing on sound pressure or sound quality may be judged at every particular time interval (e.g., every second).

The above is a description of an illustrative embodiment of the present disclosures. The present disclosures are not necessarily be limited to the configuration described above, but various variations are possible within the scope of the technical concept of the present disclosures. For example, exemplary modifications, combinations thereof as appropriate are also included in the embodiments of the present disclosures.

What is claimed is:

1. An acoustic signal processing device, comprising:
a sound pressure measurement section configured to measure a sound pressure of a sound output from a speaker;
a recording level obtaining section configured to obtain a recording level of an audio signal which is a signal representing the sound; and
a gain increasing section configured to increase a gain to the audio signal when the sound pressure measured by the sound pressure measurement section is equal to or larger than a first threshold and the recording level obtained by the recording level obtaining section is less than a second threshold.

2. The acoustic signal processing device according to claim 1,
further comprising a volume controller configured to receive a user operation to adjust a volume of the sound,
wherein, when the volume controller is operated to adjust the volume, the gain increasing section increases the gain to the audio signal on condition that the sound pressure measured by the sound pressure measurement section is equal to or larger than the first threshold and the recording level obtained by the recording level obtaining section is less than the second threshold.

3. The acoustic signal processing device according to claim 1,
further comprising:
a band divider dividing the audio signal to a plurality of frequency bands; and
a compensation section configured to compensate the audio signal of each of the frequency bands divided by the band divider using a different filtering coefficient.

4. The acoustic signal processing device according to claim 3,
further comprising a filter coefficient storage configured to store default filtering coefficient,
wherein, when the sound pressure measured by the sound pressure measurement section is less than the first threshold, the compensation section is configured to compensate for the audio signal using the default filtering coefficient.

5. The acoustic signal processing device according to claim 1,
wherein the gain increasing section is configured to increase the gain to the audio signal so that a peak sound pressure level of the audio signal becomes a full scale.

6. A non-transitory computer-readable recording medium for an acoustic signal processing device having a controller, the recording medium storing instructions which cause, when executed by the controller, the acoustic signal processing device to perform:
measuring a sound pressure of a sound output from a speaker;
obtaining a recording level of an audio signal which is a signal representing the sound; and
increasing a gain to the audio signal when the sound pressure is equal to or larger than a first threshold and the recording level is less than a second threshold.

7. An acoustic signal processing device, comprising:
a level adjustment section configured to adjust a level of an audio signal input from a sound source; and
a signal processing section configured to process the audio signal of which level is adjusted by the level adjustment section,
the signal processed by the signal processing section being transmitted to an amplifier, a sound being output by a speaker based on the audio signal amplified by the amplified,
wherein the level adjustment section includes:
a volume changing section configured to change the level of the audio signal input from the sound source in accordance with a user operation;
a sound pressure measuring section configured to measure a sound pressure of the sound output from the speaker;
a recording level obtaining section configured to obtain a recording level of the audio signal input from the sound source;
a sound pressure judgment section configured judge whether or not the sound pressure measured by the sound pressure measuring section is equal to or larger than a first threshold;
a recording level judgment section configured to judge whether the recording level of the audio signal input from. the sound source is less than a second threshold; and
a gain increasing section configured to increase a gain to the audio signal input from the volume changing section based on the recording level obtained by the recording level obtaining section when the recording level judgment section judges that the recording level is less than the second threshold,
wherein the signal processing section is configured to perform:
applying a signal processing placing emphasis on sound pressure to the audio signal input from the level adjustment section when the sound pressure judgment section judges that the sound pressure is equal to or larger than the first threshold; and
applying a signal processing placing emphasis on sound quality to the audio signal input from the level adjustment section when the sound pressure judgment section judges that the sound pressure is less than the first threshold.
